(19) United States
(12) Patent Application Publication
(10) Pub. No.: US 2009/0278107 A1
(43) Pub. Date: Nov. 12, 2009

(54) Phase change memory device

(76) Inventors: Do-Hyung Kim, Seongnam-si (KR); Jun-Soo Bae, Hwaseong-si (KR); Dong-Hyun Im, Gwacheon-si (KR); Sung-Lae Cho, Gwacheon-si (KR); Jin-II Lee, Seongnam-si (KR); Hye-Young Park, Seongnam-si (KR); Hee-Ju Shin, Yongin-si (KR)

Correspondence Address: LEE & MORSE, P.C., 3141 FAIRVIEW PARK DRIVE, SUITE 500, FALLS CHURCH, VA, 22042, US

(21) Appl. No.: 12/453,334

(22) Filed: May 7, 2009

(30) Foreign Application Priority Data
May 8, 2008 (KR) 10-2008-0043005

(51) Int. Cl. H01L 47/00

(52) U.S. Cl. 257/2; 257/E47.001

(57) ABSTRACT

The phase change memory device includes a first electrode and a second electrode and a first phase change material pattern and a second phase change material pattern interposed between the first electrode and the second electrode, wherein the first and second phase change material patterns have respectively different electrical characteristics.

### BACKGROUND

1. Field

Embodiments relate to phase change memory devices including a phase change memory having a multi-level cell.

2. Description of the Related Art

A semiconductor memory device is generally classified into a volatile memory device and a nonvolatile memory device. The volatile memory device does not retain stored information when power is no longer applied. On the other hand, the nonvolatile memory device retains stored information even when power is no longer applied power. A flash memory device with a stacked gate structure is mainly adopted as the nonvolatile memory device. However, a phase change memory device, instead of the flash memory device, is lately being suggested as a new nonvolatile memory device.

### SUMMARY

It is a feature of an embodiment to provide a phase change memory device having the improved degree of integration.

It is therefore another feature of an embodiment to provide a phase change memory having a multi-level cell.

At least one of the above and other features and advantages may be realized by providing a phase change memory device including a lower electrode and an upper electrode, and a first phase change material pattern and a second phase change material pattern, interposed between the lower electrode and the upper electrode, wherein the first and second phase change material patterns have respectively different electrical characteristics.

The first and second phase change material patterns may have respectively different widths.

At least one of the first and second phase change material patterns may have a portion where the width becomes broader as the portion becomes further away from the lower electrode.

The portion may have a section of an isosceles trapezoid shape.

The first and second phase change material patterns may have respectively different compositions.

The first and second phase change material patterns may have respectively different melting temperatures and crystallization temperatures.

The first and second phase change material patterns may include respectively different impurities.

The first and second phase change material patterns may have respectively different electric resistances.

The first and second phase change material patterns may function as a multi-level cell.

The first and second phase change material patterns may be formed by respectively different deposition methods.

The phase change memory device may further include a switching device that is electrically connected to the first and second phase change material patterns, wherein the switching device may allow currents of respectively opposite two directions to flow through the first and second phase change material patterns.

At least one of the above and other features and advantages may also be realized by providing a phase change memory device including a lower electrode on a substrate, a phase change material pattern on the lower electrode, and an upper electrode on the phase change material pattern, wherein the phase change material pattern may include a first portion of a bottom connected to the lower electrode and a second portion of a top connected to the upper electrode, the first and second portions having respectively different widths.

The width of the second portion may be broader than that of the first portion.

The width of the first portion may be uniform, and the width of the second portion may become broader as it moves from the first portion to the upper electrode.

The second portion may have an isosceles trapezoid shape.

The first and second portions may have respectively different compositions.

The first and second portions may be formed by different deposition methods.

The first and second portions may have respectively electric resistances.

At least one of the above and other features and advantages may also be realized by providing a memory system including a phase change memory device and a memory controller electrically coupled to the phase change memory device wherein the phase change memory device includes a lower electrode and an upper electrode and a first phase change material pattern and a second phase change material pattern interposed between the lower electrode and the upper electrode, wherein the first and second phase change material patterns have respectively different electrical characteristics.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A through 1D illustrate sectional views of a phase change memory device according to a first embodiment of the present invention and a method of forming the same;

FIGS. 2A through 2D illustrate sectional views of a phase change memory device according to a second embodiment of the present invention and a method of forming the same;

FIGS. 3A and 3B illustrate sectional views of a phase change memory device according to a third embodiment of the present invention and a method of forming the same;

FIGS. 4A through 4E illustrate sectional views of a phase change memory device according to a fourth embodiment of the present invention and a method of forming the same;

FIGS. 5A and 5B illustrate sectional views of a phase change memory device according to a fifth embodiment of the present invention and a method of forming the same;

FIGS. 6A and 6B illustrate sectional views of a phase change memory device according to a sixth embodiment of the present invention and a method of forming the same;

FIGS. 7A and 7B illustrate sectional views of a phase change memory device according to a seventh embodiment of the present invention and a method of forming the same;

FIGS. 8A through 8D illustrate sectional views of a phase change memory device according to an eighth embodiment of the present invention and a method of forming the same;

FIG. 9 illustrates a sectional view of a phase change memory device according to a ninth embodiment of the present invention and a method of forming the same;

FIGS. 10A through 10C illustrate sectional views of a phase change memory device according to a tenth embodiment of the present invention and a method of forming the same;

FIGS. 11A through 11C illustrate views of operation of a phase change memory device according to embodiments of the present invention; and

FIGS. 12 through 19 illustrate apparatuses including a phase change memory device according to embodiments of the present invention.

### DETAILED DESCRIPTION

Korean Patent Application No. 10-2008-0043005, filed on May 8, 2008, in the Korean Intellectual Property Office, and entitled: “Phase Change Memory Device,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

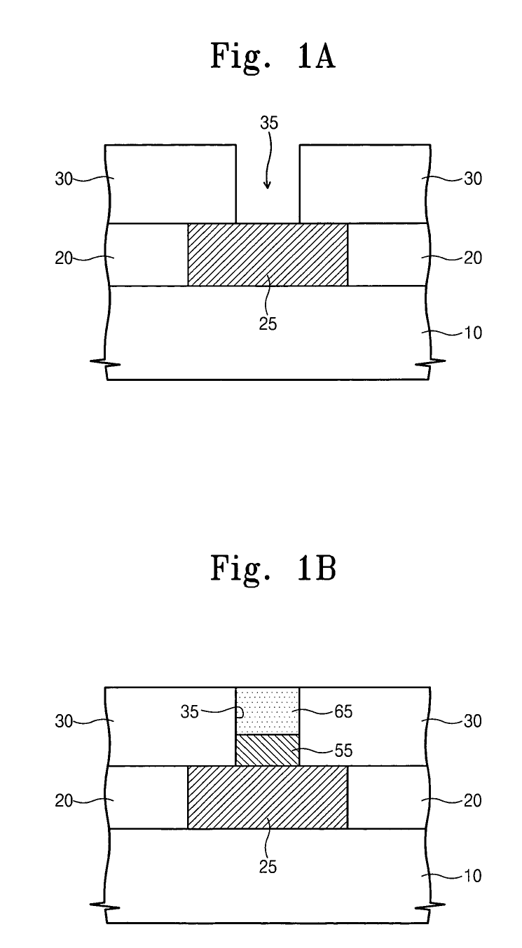

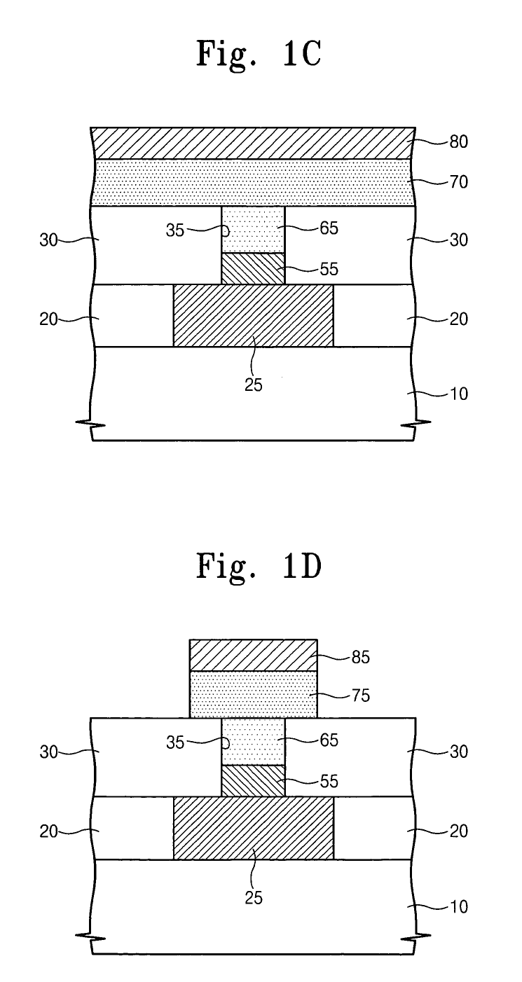

Referring to FIGS. 1A through 1D, a phase change memory device according to a first embodiment of the present invention and a method of forming the same will be described.

Referring to FIG. 1A, a first insulation layer 20 including a conductive pattern 25 may be formed on a substrate 10. The substrate 10 may be a semiconductor substrate, e.g., a single crystal silicon substrate, a Silicon On Insulator (SOI) substrate, and so forth. The substrate 10 may include a transistor that is electrically connected to the conductive pattern 25. The conductive pattern 25 may include a material having excellent heat transfer efficiency. For example, the conductive pattern 25 may include a metal, e.g., titanium, hafnium, zirconium, vanadium, niobium, tantalum, tungsten, aluminum, copper, tungsten titanium, and molybdenum, a binary metal nitride, e.g., titanium nitride, hafnium nitride, zirconium nitride, vanadium nitride, niobium nitride, tantalum nitride, tungsten nitride, and molybdenum nitride; a metal oxide, e.g., iridium oxide and ruthenium oxide, a ternary metal nitride, e.g., titanium carbon nitride, tantalum carbon nitride, titanium silicon nitride, tantalum silicon nitride, titanium aluminum nitride, tantalum aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum oxide nitride, titanium oxide nitride, and tungsten oxide nitride, silicon, or a combination of the above. In this embodiment, the conductive pattern 25 may include tungsten.

A second insulation layer 30 having a contact hole 35 to expose the conductive pattern 25 may be formed on the first insulation layer 20. The first and second insulation layers 20 and 30 may be formed of silicon oxide, silicon nitride, silicon oxide nitride, or a combination thereof. The first and second insulation layers 20 and 30 may be formed by a chemical vapor deposition (CVD) process.

Referring to FIG. 1B, a lower electrode 55 and a first phase change material pattern 65 may be formed on the conductive pattern 25 in the contact hole 35. The lower electrode 55 may be formed by a blanket anisotropic etching process after a conductive layer is formed to fill the contact hole 35. For example, the first phase change material pattern 65 may be formed by a planarization process for exposing the second insulation layer 30, after a phase change material layer is formed to fill the contact hole 35 on the lower electrode 55. The planarization process may include a chemical mechanical polishing (CMP) process or an etchback process. The phase change material layer may be formed by a CVD process, an atomic layer deposition (ALD) process, or a physical vapor deposition (PVD) process.

The lower electrode 55 may include e.g., titanium, hafnium, zirconium, vanadium, niobium, tantalum, tungsten, aluminum, copper, tungsten titanium, and molybdenum, a binary metal nitride, e.g., titanium nitride, hafnium nitride, zirconium nitride, vanadium nitride, niobium nitride, tantalum nitride, tungsten nitride, and molybdenum nitride; a metal oxide such as iridium oxide and ruthenium oxide, a ternary metal nitride, e.g., titanium carbon nitride, tantalum carbon nitride, titanium silicon nitride, tantalum silicon nitride, titanium aluminum nitride, tantalum aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum oxide nitride, titanium oxide nitride, and tungsten oxide nitride, silicon, or a combination of the above. In this embodiment, the lower electrode 55 may include titanium nitride.

The first phase change material pattern 65 may be formed of a chalcogen compound, e.g., Ge—Sb—Te (GST), Ge—Bi—Te (GBT), As—Sb—Te, As—Ge—Sb—Te, Sn—Sb—Te, In—Sn—Sb—Te, Ag—In—Sb—Te, a group 5A element-Sb—Te, a group 6A element-Sb—Te, a group 5A element-Sb—Se, a group 6A element-Sb—Se, etc. The chalcogen compound may include doped impurities. The impurities may include nitrogen, oxygen, silicon, or a combination thereof.

Referring to FIG. 1C, a phase change material layer 70 and a conductive layer 80 may be formed on the second insulation layer 30. The phase change material layer 70 may be formed on the first phase change material pattern 65. The phase change material layer 70 and the conductive layer 80 may be formed by a CVD process, an ALD process, or a PVD process.

The phase change material layer 70 may be formed of a chalcogen compound, e.g., Ge—Sb—Te (GST), Ge—Bi—Te (GBT), As—Sb—Te, As—Ge—Sb—Te, Sn—Sb—Te, In—Sn—Sb—Te, Ag—In—Sb—Te, a group 5A element-Sb—Te, a group 6A element-Sb—Te, a group 5A element-Sb—Se, a group 6A element-Sb—Se, etc. The chalcogen compound may include doped impurities. The impurities may include nitrogen, oxygen, silicon, or a combination thereof.

The conductive layer 80 may include e.g., titanium, hafnium, zirconium, vanadium, niobium, tantalum, tungsten, aluminum, copper, tungsten titanium, and molybdenum, a binary metal nitride, e.g., titanium nitride, hafnium nitride, zirconium nitride, vanadium nitride, niobium nitride, tantalum nitride, tungsten nitride, and molybdenum nitride; a metal oxide such as iridium oxide and ruthenium oxide, a ternary metal nitride, e.g., titanium carbon nitride, tantalum carbon nitride, titanium silicon nitride, tantalum silicon nitride, titanium aluminum nitride, tantalum aluminum nitride, titanium boron nitride, zirconium silicon nitride, tungsten silicon nitride, tungsten boron nitride, zirconium aluminum nitride, molybdenum silicon nitride, molybdenum aluminum nitride, tantalum oxide nitride, titanium oxide nitride, and tungsten oxide nitride, silicon, or a combination of the above. In this embodiment, the conductive layer 80 may be formed by sequentially stacking titanium and nitride titanium.

Referring to FIG. 1D, a second phase change material pattern 75 and an upper electrode 85 may be formed by patterning the phase change material layer 70 and the conductive layer 80. The second phase change material pattern 75 may be in contact with the first phase change material pattern 65. At least one difference among the sizes, e.g., the widths, compositions, deposition methods, and impurities to be doped, may exist between the first phase change material pattern 65 and the second phase change material pattern 75. The first phase change material pattern 65 and the second phase change material pattern 75 may have respectively different electrical characteristics. For example, the first phase change material pattern 65 and the second phase change material pattern 75 may have respectively different electric resistances. Also, the first phase change material pattern 65 and the second phase change material pattern 75 may have respectively different crystallization temperatures and melting temperatures. Accordingly, a phase change memory device including the first phase change material pattern 65 and the second phase change material pattern 75 may realize a multi-level cell (MLS), which will be described later.

Hereinafter, a phase change memory device according to other embodiments of the present invention will be described. The phase change memory device may include structural elements, e.g., a substrate, a conductive pattern, a phase change material layer, first and second phase change material patterns, first and second insulation layers, and first and second electrodes, e.g., lower and upper electrodes. If no description related to each element's structure material, formation process, thickness, structure, shape, and relationship with other structural parts is given, then the same characteristics as the previously described first embodiment will be applied in the subsequent discussion of other embodiments of the present invention unless otherwise particularly noted.

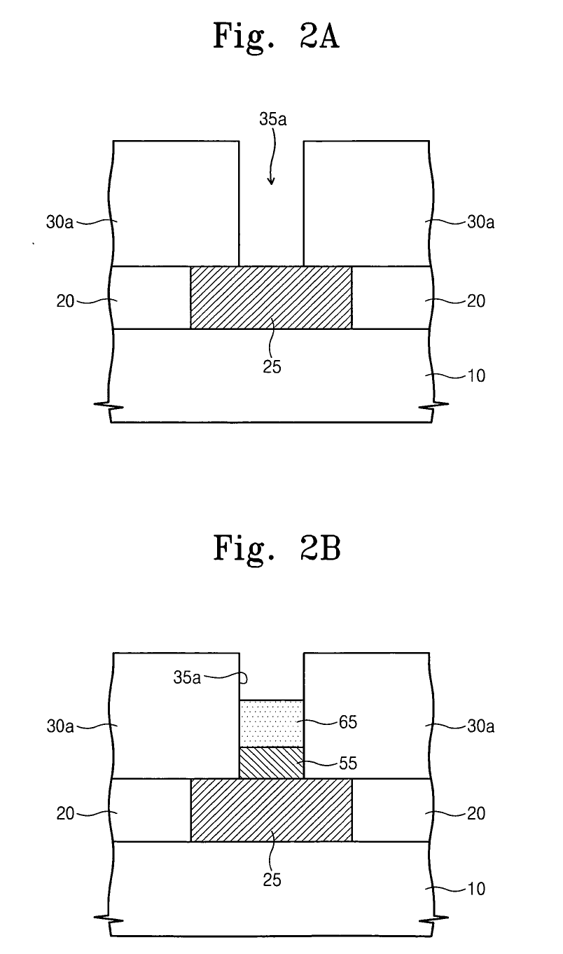

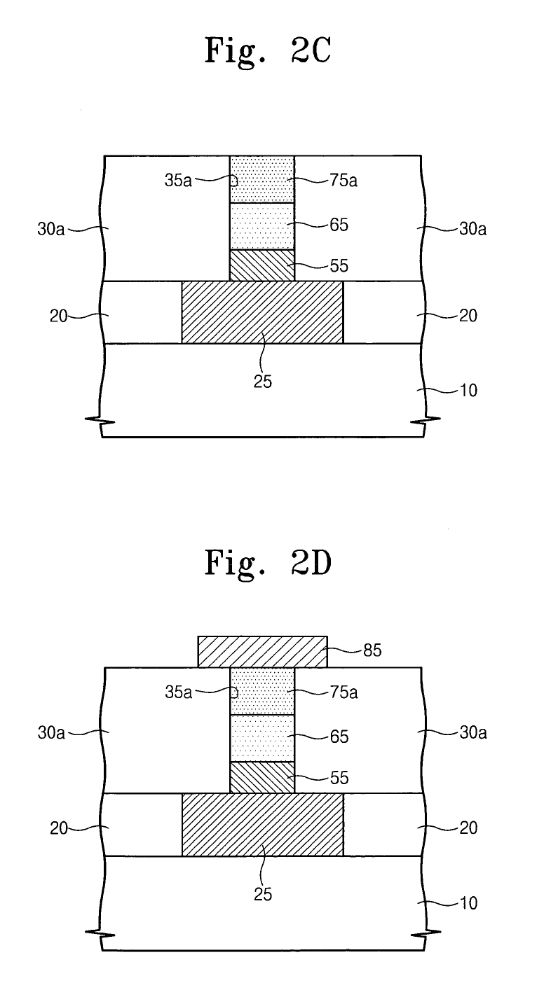

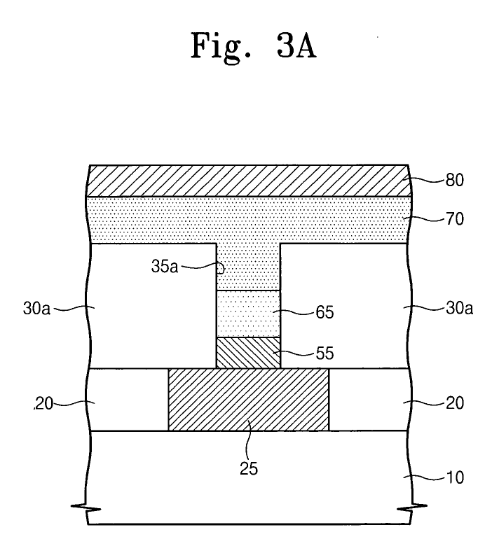

Referring to FIG. 2A through 2D, a phase change memory device according to a second embodiment of the present invention and a method of forming the same will be described.

Referring to FIG. 2A, the first insulation layer 20 including the conductive pattern 25 may be formed on the substrate 10. A second insulation layer 30a having a contact hole 35a to expose the conductive pattern 25 may be formed on the first insulation layer 20.

Referring to FIG. 2B, the lower electrode 55 and the first phase change material pattern 65 may be formed in the contact hole 35a. The first phase change material pattern 65 may be formed by a blanket anisotropic etching process after a phase change material layer is formed to fill the contact hole 35a on the lower electrode 55.

Referring to FIG. 2C, a second phase change material pattern 75a may be formed on the first phase change material pattern 65. The second phase change material pattern 75a may be formed by a planarization process, exposing the second insulation layer 30a after a phase change material layer is formed to fill the contact hole 35a on the first phase change material pattern 65. The planarization process may include a CMP process, or an etchback process.

Referring to FIG. 2D, the upper electrode 85 may be formed on the second phase change material pattern 75a. The upper electrode 85 may be formed by forming a conductive layer (not shown) on the second insulation layer 30a including the second phase change material pattern 75a and then patterning the conductive layer.

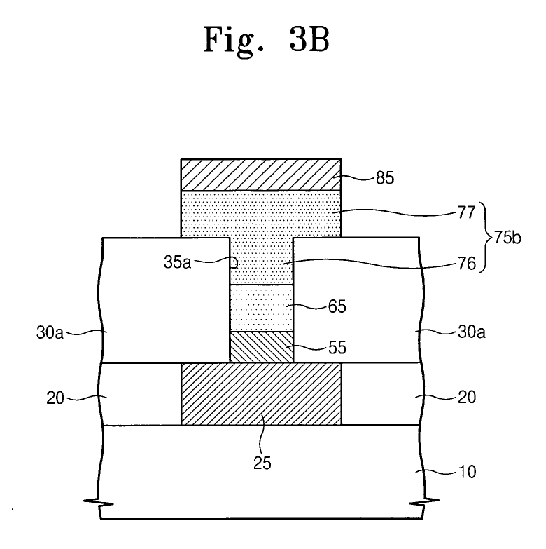

Referring to FIGS. 3A and 3B, a phase change memory device according to a third embodiment of the present invention and a method of forming the same will be described.

Referring to FIG. 3A, the phase change material layer 70 and the conductive layer 80 may be formed after the formation stage of a phase change memory device as illustrated in FIG. 2B. The phase change material layer 70 may fill the contact hole 35a on the first phase change pattern 65. The conductive layer 80 may be formed on the phase material layer 70.

Referring to FIG. 3B, a second phase change material pattern 75b and the upper electrode 85 may be formed by patterning the phase change material layer 70 and the conductive layer 80. The second phase change material pattern 75b may include a first portion 76 formed in the contact hole 35a and a second portion 77 on the second insulation layer 30a. The width of the second portion 77 may be broader than that of the first portion 76.

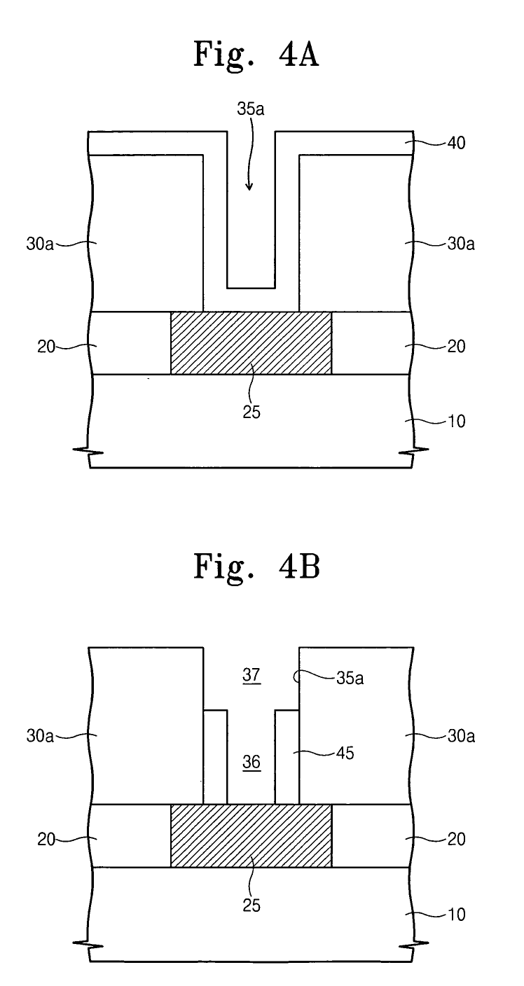

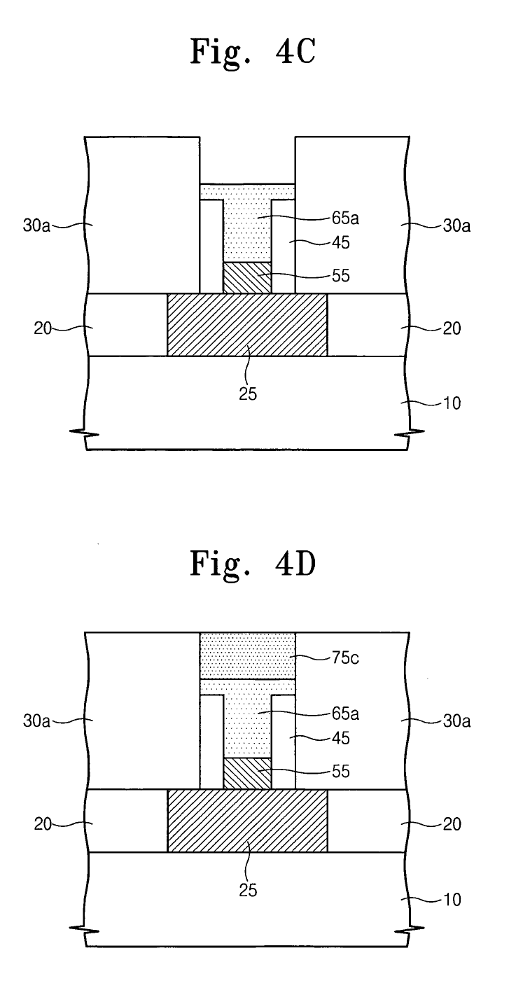

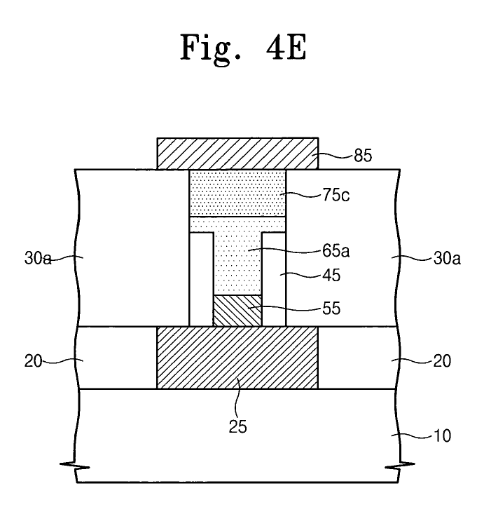

Referring to FIGS. 4A through 4E, a phase change memory device according to a fourth embodiment of the present invention and a method of forming the same will be described.

Referring to FIG. 4A, a molding insulation layer 40 may be formed after the formation stage of a phase change memory device as illustrated in FIG. 2A. The molding insulation layer 40 may be uniformly formed along the bottom surface and a sidewall of the contact hole 35a and the top surface of the second insulation layer 30a. The bottom surface of the contact hole 35a may be the top surface of the conductive pattern 25 exposed by the contact hole 35a, and the sidewall of the contact hole 35a may be the sidewall of the second insulation layer 30a that defines the contact hole 35a. The molding insulation layer 40 may be formed of a material having an etch selectivity with respect to the second insulation layer 30a.

Referring to FIG. 4B, a molding pattern 45 may be formed at a lower portion of each sidewall of the contact hole 35a by etching the molding insulation layer 40. An area of an exposed top surface of the conductive pattern may be reduced by the molding pattern 45. The contact hole 35a may include a first region 36 of a bottom defined by the molding pattern 45 and a second region 37 above the first region 36. The width of the second region 37 may be identical to that of the contact hole 35a, and the width of the first region 36 may be less than that of the contact hole 35a by twice the thickness of the molding pattern 45.

Referring to FIG. 4C, the lower electrode 55 and a first phase change material pattern 65a may be formed in the first region 36 of the contact hole 35a. The lower electrode 55 may be formed by a blanket anisotropic etching process after a conductive layer is formed on the substrate 10 where the molding pattern 45 is formed. The first phase change material pattern 65a may be formed by a blanket anisotropic etching process after a phase change material layer is formed to fill the first region 36 on the lower electrode 55. In this embodiment, a top surface of the first phase change material pattern 65a may be formed higher than that of the molding pattern 45. The first phase change material pattern 65a may be formed to cover the molding pattern 45. Alternatively, the first phase change material pattern 65a may be formed identical to or lower than the top surface of the molding pattern 45.

Referring to FIG. 4D, a second phase change material pattern 75c may be formed on the first phase change material pattern 65. The second phase change material pattern 75c may be formed through a planarization process exposing the second insulation layer 30a after a phase change material layer is formed on the first phase change material pattern 65a to fill the second region 37 of the contact hole 35a.

Referring to FIG. 4E, the upper electrode 85 may be formed on the second phase change material pattern 75c. The upper electrode 85 may be formed through a patterning process after a conductive layer is formed on the second insulation layer 30a including the second phase change material pattern 75c.

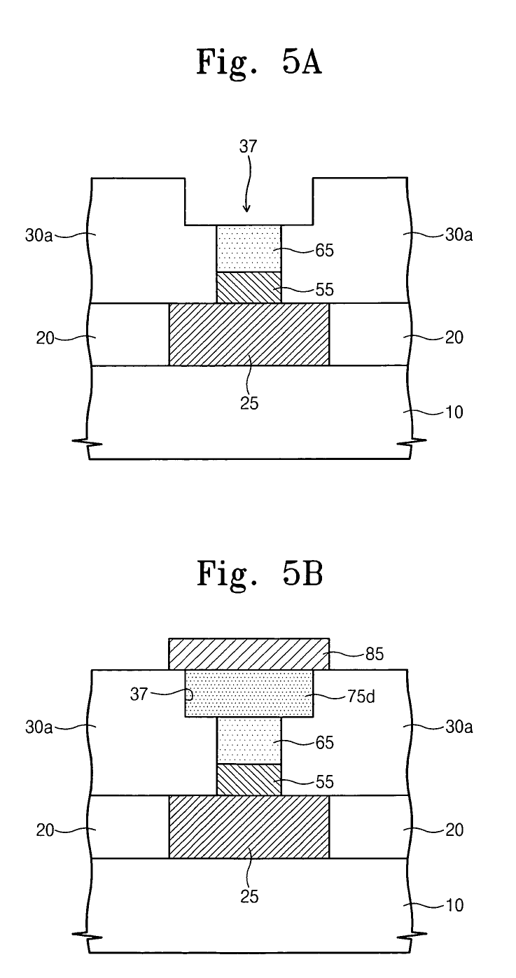

Referring to FIGS. 5A and SB, a phase change memory device according to a fifth embodiment of the present invention and a method of forming the same will be described.

Referring to FIG. 5A, an upper portion 37 of the contact hole 35a may be expanded by performing an etching process after the formation stage of a phase change memory device as illustrated in FIG. 2B. That is, the width of the upper portion 37 of the contact hole 35a becomes broader than that of the first phase change material pattern 65.

Referring to FIG. 5B, a second phase change material pattern 75d may be formed in the expanded upper portion 37 of the contact hole. The second phase change material pattern 75d may be formed by a planarization process exposing the second insulation layer 30a after a phase change material layer is formed to fill the expanded upper portion 37. The planarization process may include a CMP process or an etchback process. The width of second phase change material pattern 75d may be broader than that of the first phase change material pattern 65.

The upper electrode 85 may be formed on the second phase change material pattern 75d. The upper electrode 85 may be formed by a patterning process after a conductive layer is formed on the second insulation layer 30a including the second phase change material pattern 75.

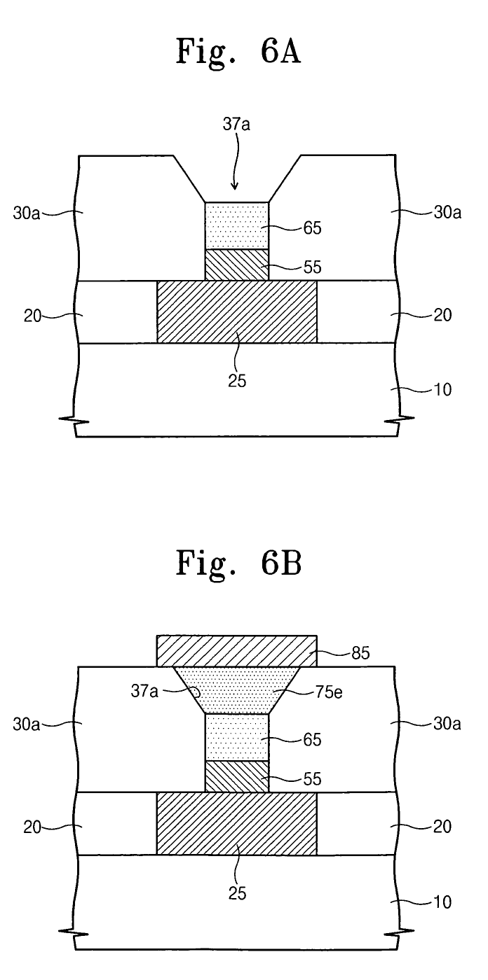

Referring to FIGS. 6A and 6B, a phase change memory device according to a sixth embodiment of the present invention and a method of forming the same will be described.

Referring to FIG. 6A, an upper portion 37a of the contact hole may be expanded by performing an etching process after the formation stage of a phase change memory device as illustrated in FIG. 2B. That is, the width of the upper portion 37a of the contact hole becomes broader than that of the first phase change material pattern 65. Unlike the other above-mentioned embodiments, however, the expanded upper portion 37a may have a slanted sidewall. That is, the width of the upper portion 37a may increase further from the first phase change material pattern 65 and the lower electrode 55.

Referring to FIG. 6B, a second phase change material pattern 75e may be formed in the expanded upper portion 37a of the contact hole. The second phase change material pattern 75e may be formed by a planarization process exposing a top surface of the second insulation layer 30a after a phase change material layer is formed to fill the expanded upper portion 37a. The planarization process may include a CMP process, or an etchback process. The width of the second phase change material pattern 75e may be broader than that of the first phase change material pattern 65. The second phase change material pattern 75e may have slant sidewalls. That is, the width of the second phase change material pattern 75e becomes broader as it becomes further away from the first phase change material pattern 65 and the lower electrode 55. The section of the second phase change material pattern 75e may have an isosceles trapezoid shape.

The upper electrode 85 may be formed on the second phase change material pattern 75e. The upper electrode 85 may be formed by a patterning process after a conductive layer may be formed on the second insulation layer 30a including the second phase change material pattern 75e.

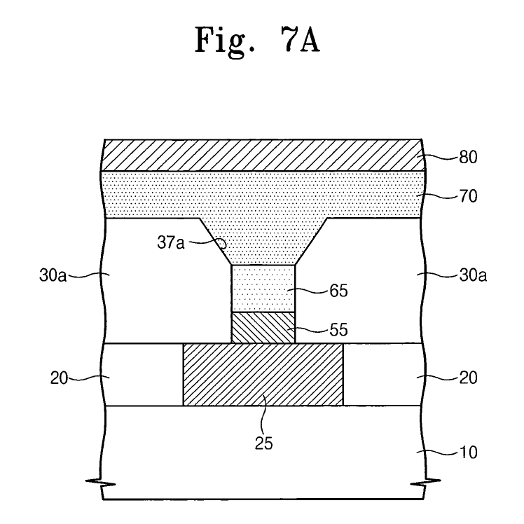

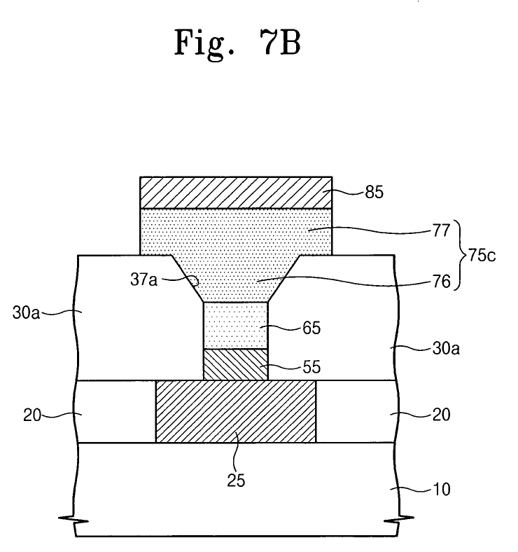

Referring to FIGS. 7A and 7B, a phase change memory device according to a seventh embodiment of the present invention and a method of forming the same will be described.

Referring to FIG. 7A, the phase change material layer 70 and the conductive layer 80 may be formed after the formation stage of a phase change memory device as illustrated in FIG. 6A. The phase change material layer 70 may fill the expanded upper portion 37a of the first phase change pattern 65.

Referring to FIG. 7B, a second phase change material pattern 75c and the upper electrode 85 may be formed by patterning the phase change material layer 70 and the conductive layer 80. The second phase change material pattern 75c may include a first portion 76 formed in the expanded upper portion 37a of the contact hole 35a and a second portion 77 extending from the first portion to the second insulation layer 30a. The width of the second portion 77 may be broader than that of the first portion 76. The first portion 76 may have slant sidewalls. That is, the width of the first portion 76 becomes broader as it becomes further away from the first phase change material pattern 65 and the lower electrode 55. The section of the first portion 76 may have an isosceles trapezoid shape.

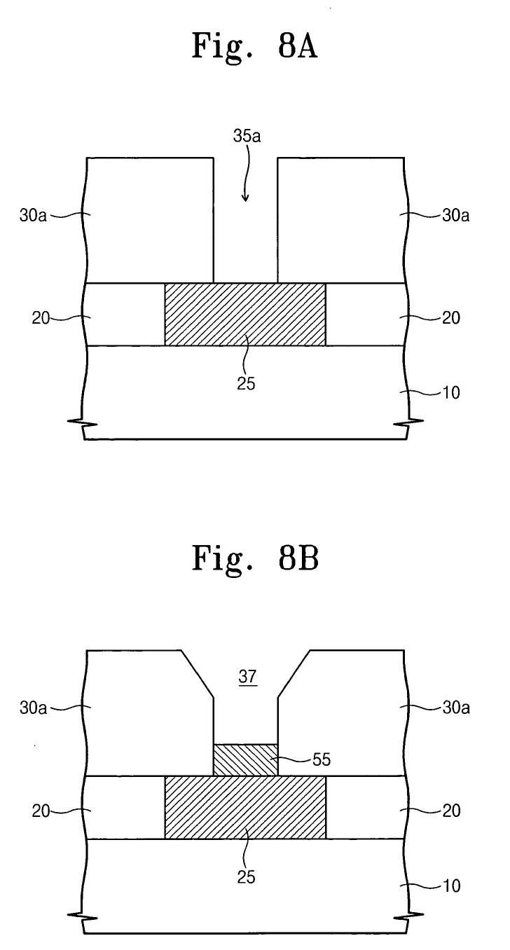

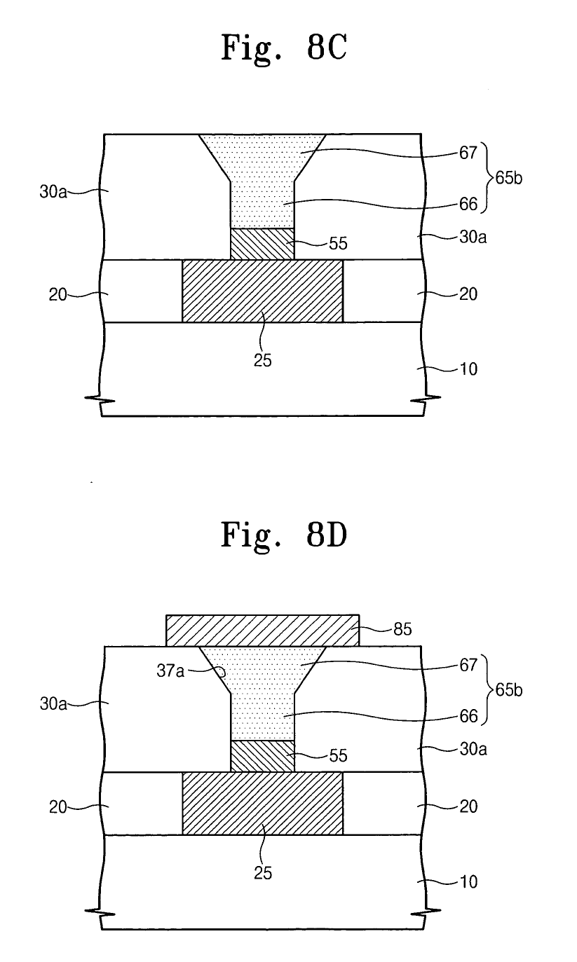

Referring to FIGS. 8A through 8D, a phase change memory device according to an eighth embodiment of the present invention and a method of forming the same will be described.

Referring to FIG. 8A, the first insulation layer 20 including the conductive pattern 25 may be formed on the substrate 10. The second insulation layer 30 including a contact hole 35a to expose the conductive pattern 25 may be formed on the first insulation layer 20.

Referring to FIG. 8B, the lower electrode 55 may be formed in the contact hole 35a. The lower electrode 55 may be formed by an etching process after a conductive layer is formed to fill the contact hole 35a. Anisotropic etching and isotropic etching processes may be combined to extend the upper portion 37a of the contact hole 35a during the etching process.

Referring to FIG. 8C, a first phase change material pattern 65b may be formed in the contact hole 35a. The first phase change material pattern 65b may be formed by a planarization process, exposing the second insulation layer 30a after a phase change material layer is formed to fill the contact hole 35a. The first phase change material pattern 65b may include a first portion 66 at the bottom and a second portion 67 at the top. The second portion 67 may have a slanted sidewall. That is, the width of the second portion 67 may increase further from the first portion 66 and the lower electrode 55.

Referring to FIG. 8D, the upper electrode 85 may be formed on the first phase change material pattern 65b. The upper electrode 85 may be formed by a patterning process after a conductive layer is formed on the second insulation layer 30a including the first phase change material pattern 65b.

According to this embodiment, even when only one phase change material pattern 65b is included, the portions 66 and 67 having respectively different widths may be included. Therefore, the phase change material pattern 65b may function as a multi-level cell.

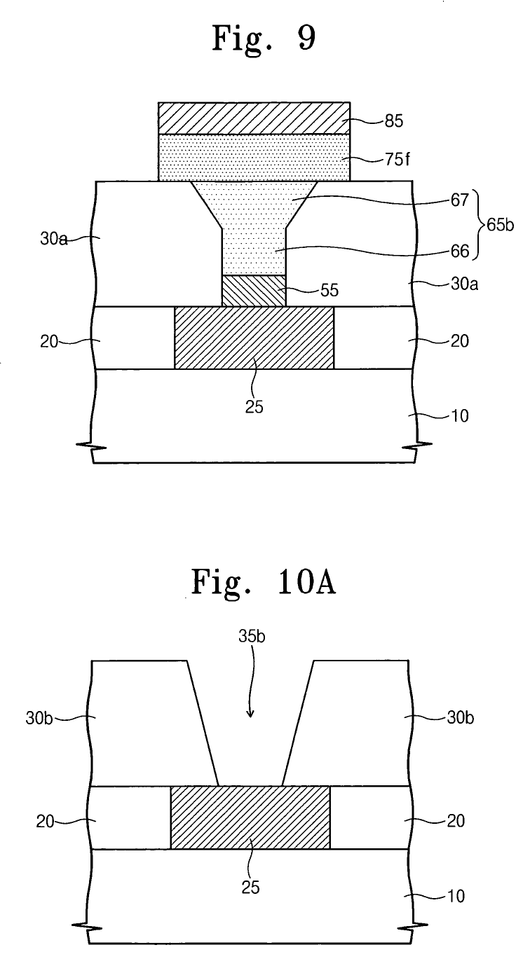

Referring to FIG. 9, a phase change memory device according to a ninth embodiment of the present invention and a method of forming the same will be described.

Referring to FIG. 9, a second phase change material pattern 75f and the upper electrode 85 may be formed on the first phase material pattern 65b of FIG. 8C. The second phase change material pattern 75f and the upper electrode 85 may be formed by a patterning process after a phase change material and a conductive layer may be sequentially formed on the second insulation layer 30a including the first phase change material pattern 65b.

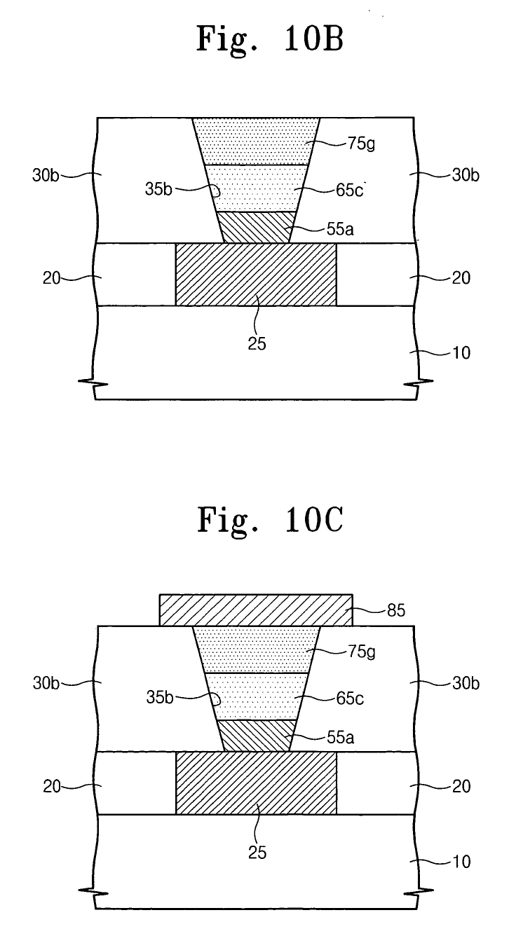

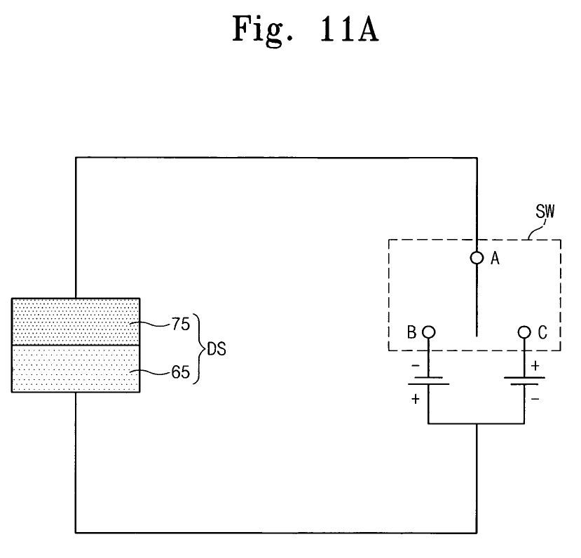

Referring to FIGS. 10A through 10C, a phase change memory device according to a tenth embodiment of the present invention and a method of forming the same will be described.

Referring to FIG. 10A, the first insulation layer 20 including the conductive pattern 25 may be formed on the substrate 10. A second insulation layer 30b including a contact hole 35b to expose the conductive pattern 25 may be formed on the first insulation layer 20. The contact hole 35b may have a slanted sidewall. That is, the width of the contact hole 35b becomes broader as it becomes further away from the conductive pattern 25.

Referring to FIG. 10B, a lower electrode 55a, a first phase change material pattern 65c, and a second phase change material pattern 75g may be sequentially formed in the contact hole 35b. The lower electrode 55a may be formed by a blanket anisotropic etching process after a conductive layer is formed on the conductive pattern 25. The first phase material pattern 65c may be formed by a blanket anisotropic etching process after a phase change material layer is formed on the lower electrode 55a. The second phase change material pattern 75g may be formed by a planarization process exposing the second insulation layer 30b after a phase change material layer is formed on the first phase change material pattern 65c.

Referring to FIG. 10C, the upper electrode 85 may be formed on the second phase change material pattern 75g. The upper electrode 85 may be formed by a patterning process after a conductive layer is formed on the second insulation layer 30b including the second phase change material pattern 75g.

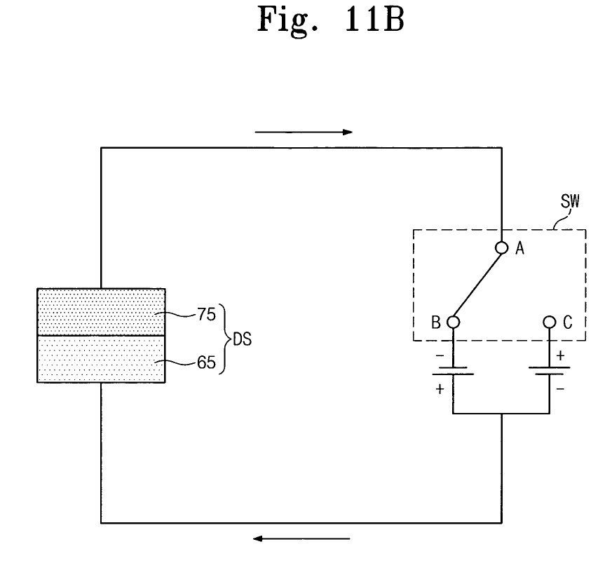

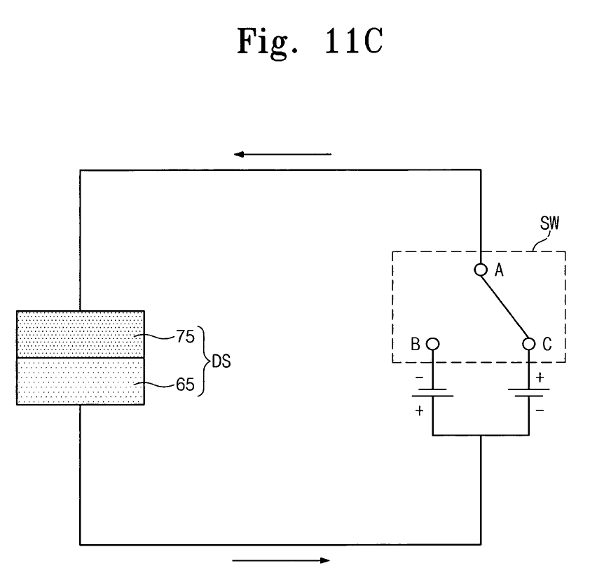

Referring to FIGS. 11A through 11C, an operation method of the phase change memory devices according to embodiments of the present invention will be described. In the following discussion, all elements will be referred to by their base reference numeral. It is to be understood that this explanation is reference to any of the embodiments.

Referring to FIGS. 11A through 11C, the phase change memory device may include a data storage element DS and a switching device SW. The data storage element DS may include a first phase change material pattern 65 and a second phase change material pattern 75. As mentioned above, the first phase change material pattern 65 and the second phase change material pattern 75 may have respectively different electrical characteristics because there is at least one difference, e.g., sizes, structures, deposition methods and/or doped impurities thereof between the first and second phase change material patterns 65 and 75. The first phase change material pattern 65 may have a first crystallization temperature and a first melting temperature. The second phase change material pattern 75 may have a second crystallization temperature and a second melting temperature. The first and second crystallization temperatures may be different from each other. The first and second melting temperatures may be different from each other.

Since the first and second phase change material patterns 65 and 75 may exist in a crystalline state or an amorphous state, the data storage element DS including the first and second phase change material patterns 65 and 75 may realize four states. When a phase change material pattern is in a crystalline state, it is represented with 0, and when a phase change material pattern is in an amorphous state, it is represented with 1. That is, when both the first and second phase change material patterns 65 and 75 are in the crystalline state, the data storage element DS may be represented with a state (0,0), and when both the first and second phase change material patterns 65 and 75 are in the amorphous state, the data storage element DS may be represented with a state (1,1). Additionally, when the first phase change material pattern 65 is in the crystalline state and the second phase change material pattern 75 is in the amorphous state, the data storage element DS may be represented with (0,1). Also, when the first phase change material pattern 65 is in the amorphous state and the second phase change material pattern 75 is the crystalline state, the data storage element DS may be represented with (1,0).

The data storage element DS may be electrically connected to the switching device SW. The switching device SW includes terminals A, B, and C. According to connection status of the terminals A, B, and C, a direction of current flowing through the data storage element DS may be changed. As illustrated in FIG. 11B, when the terminals A and B are electrically connected, current flows in a clockwise direction (hereinafter, referred to as a forward direction). As illustrated in FIG. 11C, when the terminals A and C are electrically connected, current flows in a counterclockwise direction (hereinafter, referred to as a reverse direction).

Referring to FIG. 11A, both the first and second phase change material patterns 65 and 75 are in a crystalline state. Thus, the data storage element DS may be represented with a state (0,0). The data storage element DS of the state (0,0) may have an electrical resistance of below 3 kΩ.

Referring to FIG. 11B, when the data storage element DS is in a state (0,0) and the terminals A and B of the switching device SW are electrically connected, forward current flows through the first and second phase change material patterns 65 an 75. The second phase change pattern 75 is heated above the second melting temperature by the forward current and then cooled, changing into an amorphous state. Accordingly, the data storage element DS changes from the state (0,0) into the state (0,1).

Referring to FIG. 11C, when the data storage element DS is in the state (0,0) and the terminals A and C of the switching device SW are electrically connected, reverse current flows through the first and second phase change material patterns 65 and 75. The first phase change material pattern 65 is heated above the first melting temperature by the reverse current and then cooled, changing into an amorphous state. Accordingly, the data storage element DS changes from the state (0,0) into the state (1,0). The data storage element DS of the state (0,1) may have an electric resistance of about 5 kΩ to about 15 kΩ. The data storage element DS of the state (1,0) may have an electric resistance of about 40 kΩ to about 100 kΩ.

Referring to FIGS. 11B and 11C, by changing a connection path of the switching device SW, the forward current flowing through the first and second phase change material patterns 65 and 75 may be changed into a reverse direction, and also, the reverse current may be changed into the forward current. The first phase change material pattern 65 or the second phase change material pattern 75 is heated above the first melting temperature or the second melting temperature through the direction-changed current and then cooled, such that it may change from a crystalline state into an amorphous state. Accordingly, the data storage element DS changes from the state (0,1) or the state (1,0) into the state (1,1). The data storage element DS of the state (1,1) has an electric resistance of about 200 kΩ to about 1 MΩ.

In this embodiment, due to the forward current, the state of the second phase change material pattern 75 may be changed, and due to the reverse current, the state of the first phase change material pattern 65 may be changed. Alternatively, the state of the first phase change material pattern 65 may be changed due to the forward current, and the state of the second phase change material pattern 75 may be changed due to the reverse current. The first and second phase change material patterns 65 and 75 in the amorphous state may be heated between the first crystallization temperature and the first melting temperature or between the second crystallization temperature and the second melting temperature, through the forward current or the reverse current, and then are cooled, such that they return to the crystalline state again.

As mentioned above, the data storage element DS of the memory device according to the above embodiment includes first and second phase change material patterns 65 and 75 having the respectively different electrical characteristics. Therefore, the data storage element DS can have respectively different four electric resistances, and thus, can function as a multi-level cell. Accordingly, a multi-bit memory device can be realized.

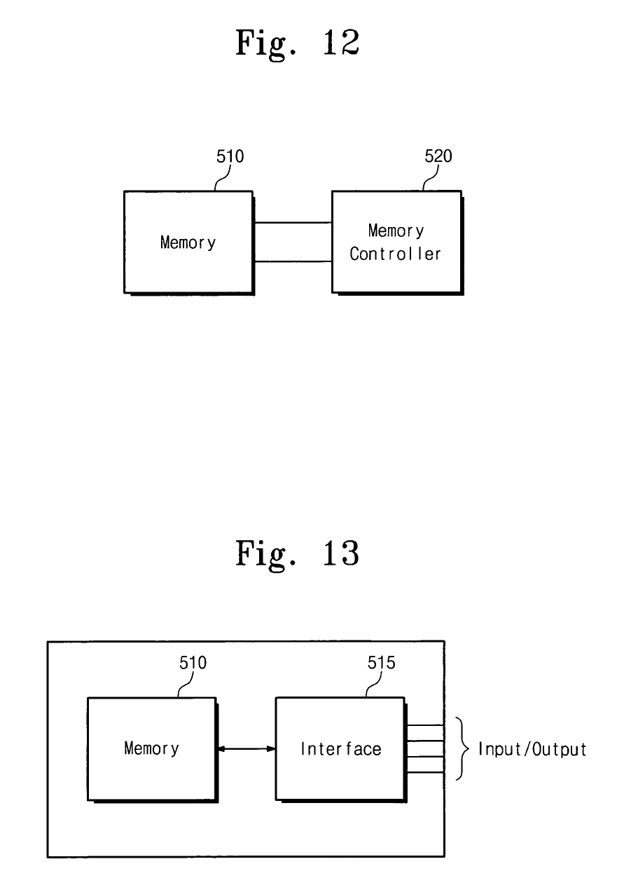

FIG. 12 illustrates an apparatus including a phase change memory device according to an embodiment of the present invention. As shown in the drawing, the apparatus of the present embodiment includes a memory 510 and a memory controller 520. The memory 510 may include a phase change memory device according to the above-described embodiments of the present invention. The memory controller 520 may supply an input signal to control an operation of the memory 510. For example, the memory controller 520 may supply a command language and an address signal. The memory controller 520 may control the memory 510 based on a received control signal.

FIG. 13 illustrates an apparatus including a phase change memory device according to an embodiment of the present invention. As shown in the drawing, the apparatus of the present embodiment includes a memory 510 connected to an interface 515. The memory 510 may include a memory device according to the aforementioned embodiments of the present invention. The interface 515 may provide, for example, an external input signal. For example, the interface 515 may provide a command language and an address signal. The interface 515 may control the memory 510 based on a control signal which is generated from an outside and received.

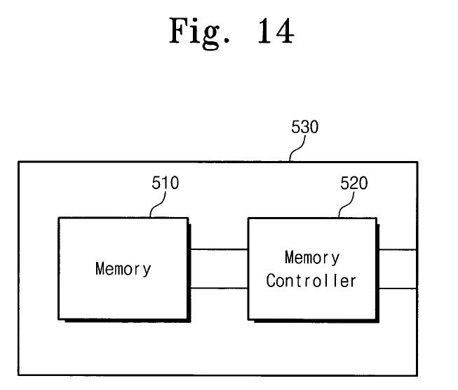

FIG. 14 illustrates an apparatus including a phase change memory device according to an embodiment of the present invention. As shown in the drawing, the apparatus of the present invention is similar to the apparatus of FIG. 12, except that the memory 510 and the memory controller 520 are embodied by a memory card 530. For example, the memory card 530 may be a memory card satisfying a standard for compatibility with electronic appliances, e.g., digital cameras, personal computers or the like. The memory controller 520 may control the memory 510 based on a control signal which the memory card receives from a different device, for example, an external device.

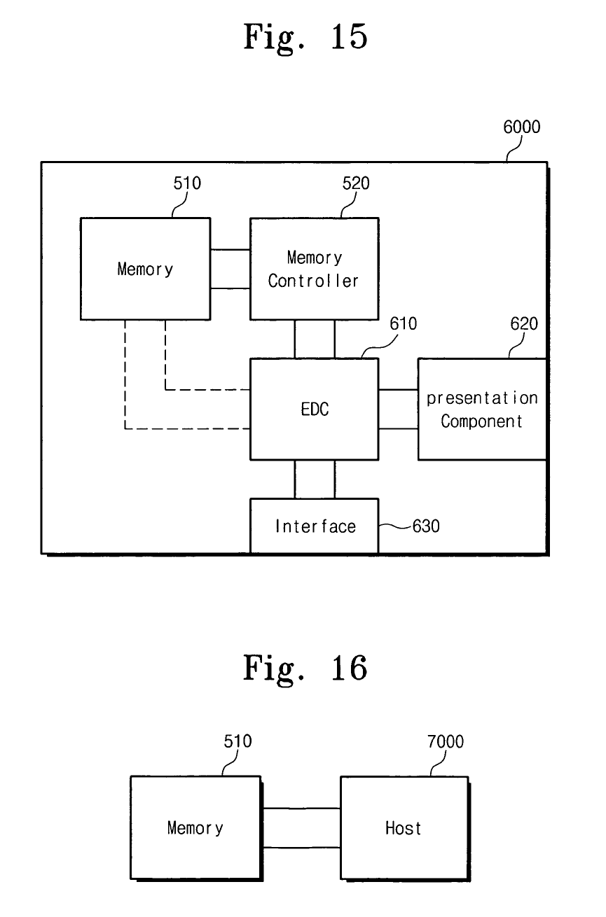

FIG. 15 illustrates a mobile device 6000 including a phase change memory device according to an embodiment of the present invention. The mobile device 6000 may be an MP3, a video player, a video, audio player or the like. As illustrated in the drawing, the mobile device 6000 includes the memory 510 and the memory controller 520. The memory 510 may include a phase change memory device according to the aforementioned embodiments of the present invention. The mobile device 6000 may include an encoder and decoder EDC 610, a presentation component 620, and an interface 630. Data such as videos and audios may be exchanged between the memory 510 and the encoder and decoder EDC 610 via the memory controller 520. As indicated by a dotted line, data may be directly exchanged between the memory 510 and the encoder and decoder EDC 610.

EDC 610 may encode data to be stored in the memory 510. For example, EDC 610 may encode audio data into an MP3 file and store the encoded MP3 file in the memory 510. Alternatively, EDC 610 may encode MPEG video data (e.g., MPEG3, MPEG4, etc.) and store the encoded video data in the memory 510. Also, EDC 610 may include a plurality of encoders that encode different data type according to different data formats. For example, EDC 610 may include an MP3 encoder for audio data and an MPEG encoder for video data. EDC 610 may decode output data from the memory 510. For example, EDC 610 may decode audio data output from the memory 510 into an MP3 file. Alternatively, EDC 610 may decode video data output from the memory 510 into an MPEG file. Also, EDC 610 may include a plurality of decoders that decode a different type of data according to a different data format. For example, EDC 610 may include an MP3 decoder for audio data and an MPEG decoder for video data. Also, EDC 610 may include only a decoder. For example, previously encoded data may be delivered to EDC 610, decoded, and then delivered to the memory controller 520 and/or the memory 510.

EDC 610 may receive data to encode or previously encoded data via the interface 630. The interface 630 may comply with a well-known standard, e.g., USB, firewire, etc. The interface 630 may include one or more interfaces, e.g., a firewire interface, a USB interface, etc. The data provided from the memory 510 may be output via the interface 630.

The presentation component 620 may represent data decoded by the memory 510 and/or EDC 610 such that a user can perceive the decoded data. For example, the presentation component 620 may include a display screen displaying a video data, etc., and a speaker jack to output an audio data.

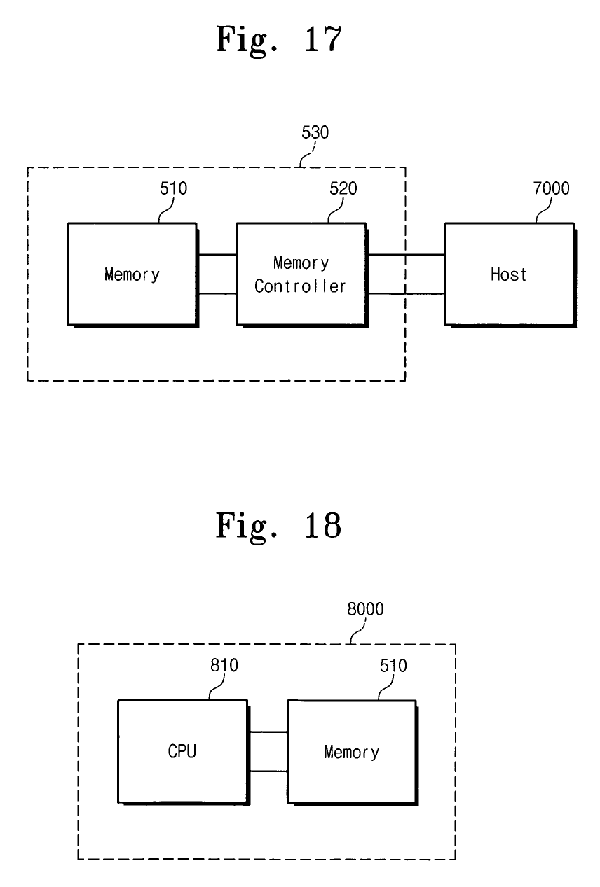

FIG. 16 illustrates an apparatus including a phase change memory device according to an embodiment of the present invention. As shown in the drawing, the memory 510 may be connected to a host system 7000. The memory 510 includes a phase change memory device according to the aforementioned embodiments of the present invention. The host system 7000 may be a processing system, e.g., a personal computer, a digital camera, etc. The memory 510 may be a detachable storage medium, e.g., a memory card, a USB memory, or a solid-state driver SSD. The host system 7000 may provide an input signal, e.g., a command language and an address signal, controlling an operation of the memory 510.

FIG. 17 illustrates an apparatus including a phase change memory device according to an embodiment of the present invention. In this embodiment, the host system 7000 may be connected to the memory card 530. The host system 7000 may supply a control signal to the memory card 530, enabling the memory controller 520 to control operation of the memory 510.

FIG. 18 illustrates an apparatus including a phase change memory device according to an embodiment of the present invention. As illustrated in the drawing, the memory 510 may be connected with a central processing unit CPU 810 of a computer system 8000. For example, the computer system 8000 may be a personal computer, a personal data assistant, etc. The memory 510 may be connected to the CPU 810 via a bus.

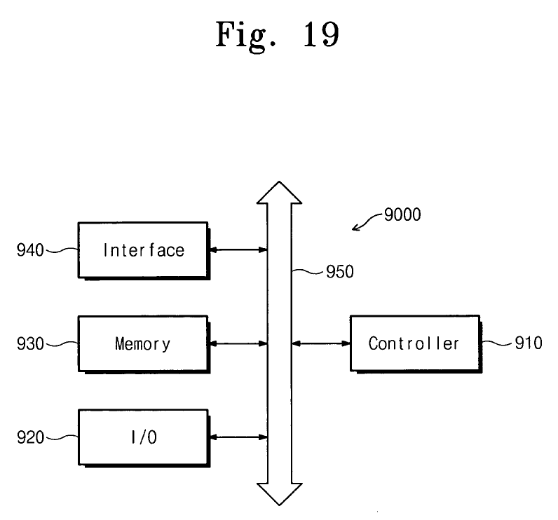

FIG. 19 illustrates an apparatus including a phase change memory device according to an embodiment of the present invention. As shown in FIG. 19, the apparatus 9000 according to the present embodiment may include a controller 910, an input/output unit 920, e.g., a keyboard, a display or the like, a memory 930, and an interface 940. In the present embodiment, the respective components constituting the apparatus may be connected to each other via a bus 950.

The controller 910 may include at least one microprocessor, digital processor, microcontroller, or processor. The memory 930 may store a command executed by data and/or the controller 910. The interface 940 may be used to transmit data from a different system, for example, a communication network, or to a communication network. The apparatus 9000 may be a mobile system, e.g., a PDA, a portable computer, a web tablet, a wireless phone, a mobile phone, a digital music player, a memory card or a different system that can transmit and/or receive information.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A phase change memory device, comprising:
a first electrode and a second electrode; and
a first phase change material pattern and a second phase change material pattern interposed between the first electrode and the second electrode,
wherein the first and second phase change material patterns have respectively different electrical characteristics.

2. The phase change memory device as claimed in claim 1, wherein the first and second phase change material patterns have respectively different widths.

3. The phase change memory device as claimed in claim 1, wherein at least one of the first and second phase change material pattern has a portion where the width of the portion becomes broader as the portion becomes further away from the first electrode.

4. The phase change memory device as claimed in claim 3, wherein the portion has a section of an isosceles trapezoid shape.

5. The phase change memory device as claimed in claim 1, wherein the first and second phase change material patterns have respectively different compositions.

6. The phase change memory device as claimed in claim 1, wherein the first and second phase change material patterns have respectively different melting temperatures and crystallization temperatures.

7. The phase change memory device as claimed in claim 1, wherein the first and second phase change material patterns comprises respectively different impurities.

8. The phase change memory device as claimed in claim 1, wherein the first and second phase change material patterns have respectively different electric resistances.

9. The phase change memory device as claimed in claim 1, wherein the first and second phase change material patterns function as a multi-level cell.

10. The phase change memory device as claimed in claim 1, wherein the first and second phase change material patterns are formed by respectively different deposition methods.

11. The phase change memory device as claimed in claim 1, further comprising a switching device that is electrically connected to the first and second phase change material patterns,
wherein the switching device allows currents of respectively opposite two directions to flow through the first and second phase change material patterns.

12. A phase change memory device, comprising:
a lower electrode on a substrate;
a phase change material pattern on the lower electrode; and
an upper electrode on the phase change material pattern,
wherein the phase change material pattern includes a first portion of a bottom connected to the lower electrode and a second portion of a top connected to the upper electrode, the first and second portions having respectively different widths.

13. The phase change memory device as claimed in claim 12, wherein the width of the second portion is broader than that of the first portion.

14. The phase change memory device as claimed in claim 13, wherein the width of the first portion is uniform, and the width of the second portion becomes broader as it moves from the first portion to the upper electrode.

15. The phase change memory device as claimed in claim 12, wherein the second portion has an isosceles trapezoid shape.

16. The phase change memory device as claimed in claim 12, wherein the first and second portions have respectively different compositions.

17. The phase change memory device as claimed in claim 12, wherein the first and second portions are formed by respectively different deposition methods.

18. The phase change memory device as claimed in claim 12, wherein the first and second portions have respectively different electric resistances.

19. A memory system, comprising:
a phase change memory device, and
a memory controller electrically coupled to the phase change memory device, wherein the phase change memory device includes:
a lower electrode and an upper electrode; and
a first phase change material pattern and a second phase change material pattern interposed between the first electrode and the second electrode,
wherein the first and second phase change material patterns have respectively different electrical characteristics.
